(19) United States
(12) Patent Application Publication
(10) Pub. No.: US 2026/0282725 A1
(43) Pub. Date: Sep. 17, 2026

(54) DISPLAY DEVICE

(71) Applicant: LG Display Co., Ltd., Seoul (KR)

(72) Inventors: Byeonggon KIM, Paju-si (KR); Sumin AN, Paju-si (KR); Jisub PARK, Paju-sik, (KR)

(21) Appl. No.: 19/415,637

(22) Filed: Dec. 10, 2025

(30) Foreign Application Priority Data
Mar. 17, 2025 (KR) 10-2025-0033884

(51) Int. Cl. H10K 59/80; H10K 59/122

(52) U.S. Cl. CPC H10K 59/8791; H10K 59/122; H10K 59/873

(57) ABSTRACT

A display device including a substrate having a display area including a plurality of sub-pixels, and a non-display area disposed around the display area; a first electrode disposed in the sub-pixels; a bank disposed on the first electrode in the display area and positioned at a boundary between adjacent sub-pixels of the plurality of sub-pixels; and an optical inorganic layer disposed on the bank and covering side surfaces and an upper surface of the bank, in which the bank includes a black-based material, and a refractive index of the optical inorganic layer is lower than a refractive index of the bank.

### CROSS REFERENCE TO RELATED APPLICATION

This application claims priority from and the benefit of Korean Patent Application No. 10-2025-0033884, filed on Mar. 17, 2025, which is hereby incorporated by reference for all purposes as if fully set forth herein.

### BACKGROUND

### FIELD

Embodiments of the invention relate generally to a display device.

### DISUCSSION OF THE BACKGROUND

As the information society develops, various demands for display devices for displaying images are increasing, and various types of display devices such as liquid crystal display (LCD) devices and organic light emitting diode (OLED) display devices are utilized.

A display device includes a plurality of pixels and a plurality of switching elements for driving and controlling the pixels.

The above information disclosed in this Background section is only for understanding of the background of the inventive concepts, and, therefore, it may contain information that does not constitute prior art.

### SUMMARY

Embodiments of the inventive concepts are directed to providing a display device capable of preventing external light reflection.

Embodiments of the inventive concepts are also directed to providing a display device capable of delaying or preventing moisture penetration into a non-display area.

Embodiments of the inventive concepts are also directed to providing a low-reflection display device driven at low power.

Additional features of the inventive concepts will be set forth in the description which follows, and in part will be apparent from the description, or may be learned by practice of the inventive concepts.

A display device according to an embodiment includes a substrate having a display area including a plurality of sub-pixels, and a non-display area disposed around the display area; a first electrode disposed in the sub-pixels; a bank disposed on the first electrode in the display area and positioned at a boundary between adjacent sub-pixels of the plurality of sub-pixels; and an optical inorganic layer disposed on the bank and covering side surfaces and an upper surface of the bank, in which the bank includes a black-based material, and refractive index of the optical inorganic layer is lower than a refractive index of the bank.

The optical inorganic layer may expose a central portion of the first electrode.

The display device may further include an organic layer disposed on the optical inorganic layer, and the organic layer is in direct contact with the central portion of the first electrode exposed by the optical inorganic layer.

The optical inorganic layer may be a porous inorganic layer, and the optical inorganic layer has a plurality of pores disposed therein.

The plurality of pores may each have a diameter of 0.3 μm or more.

The optical inorganic layer may be in direct contact with the side surfaces and the upper surface of the bank.

The display device may further include a spacer disposed on the bank, and the optical inorganic layer is in direct contact with an upper surface of the spacer.

The display device may further include a dam disposed on the substrate in the non-display area, and the optical inorganic layer overlaps the dam.

The optical inorganic layer may be in direct contact with side surfaces and an upper surface of the dam.

The dam may include a first layer, a second layer disposed on the first layer, and a third layer disposed on the second layer. Furthermore, the second layer may include a bank, the third layer may include a spacer, and the optical inorganic layer may be in direct contact with the spacer.

The display device may further include a first transistor disposed between the substrate and the first electrode; a second transistor disposed between the first transistor and the first electrode; a connection electrode disposed between the second transistor and the first electrode; a first protective layer disposed between the second transistor and the connection electrode; and a second protective layer disposed between the connection electrode and the first electrode. Additionally, the first layer may include the second protective layer.

A semiconductor layer of the first transistor may include polysilicon, and a semiconductor layer of the second transistor may include an oxide.

The optical inorganic layer may be in direct contact with an upper surface of the substrate exposed by the dam.

A display device according to another embodiment includes a substrate including a display area including a plurality of sub-pixels, and a non-display area disposed around the display area; a first electrode disposed in the sub-pixels; a bank disposed on the first electrode in the display area and positioned at a boundary between adjacent sub-pixels of the plurality of sub-pixels; and an optical inorganic layer disposed on the bank and covering side surfaces and an upper surface of the bank, in which the bank includes a black-based material, and a plurality of pores are disposed inside the optical inorganic layer.

Each of the plurality of pores may have a diameter of 0.3 μm or more.

Each sub-pixel of the plurality of sub-pixels may include light-emitting areas exposed by the bank, and the optical inorganic layer may overlap a portion of the light-emitting area.

The optical inorganic layer may be in direct contact with the side surfaces and the upper surface of the bank.

The display device may further include a spacer disposed on the bank, and the optical inorganic layer is in direct contact with an upper surface of the spacer.

The display device may further include a dam disposed on the substrate in the non-display area, and the optical inorganic layer overlaps the dam.

The optical inorganic layer may be in direct contact with side surfaces and an upper surface of the dam.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a plan view of a display device according to one embodiment.

FIG. 2 is a side view illustrating a bent state of the display device according to FIG. 1.

FIG. 3 is a cross-sectional view along line A-A’, shown in FIG. 1.

FIG. 4 is a cross-sectional view of a touch part according to FIG. 3.

FIG. 5 is a cross-sectional view along line B-B’, shown in FIG. 1.

FIG. 6 is a cross-sectional view along line C-C’, shown in FIG. 1.

FIG. 7 is a plan view of a display panel according to one embodiment.

FIG. 8 is an enlarged cross-sectional view of area Q1 shown in FIG. 3.

FIG. 9 is an enlarged cross-sectional view of area Q2 shown in FIG. 8.

FIG. 10 is a cross-sectional view of a display panel according to another embodiment.

FIG. 11 is a cross-sectional view of a display panel according to still another embodiment.

FIG. 12 is a cross-sectional view of the display panel according to yet another embodiment.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z – axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” may encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

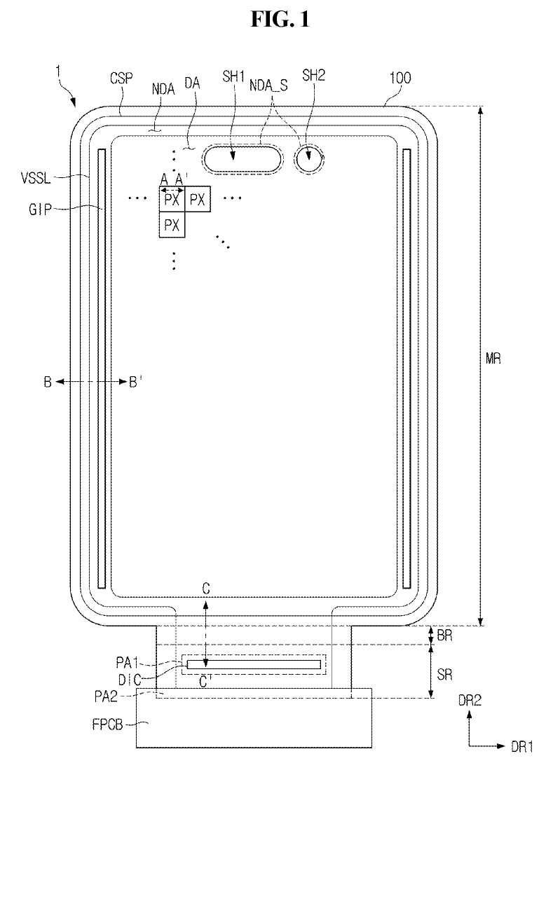

FIG. 1 is a plan view of a display device according to one embodiment.

Referring to FIG. 1, a display device 1 according to one embodiment may include a display panel 100. The display panel 100 may include a display area DA including a plurality of pixels PX and a non-display area NDA around the display area DA. The flat surface shape of the display area DA may have a rectangular shape. However, the embodiments disclosed herein are not limited thereto, and the flat surface shape of the display area DA may be a square, circular, elliptical, or other polygonal shapes. For example, the display area DA may have a rectangular shape with rounded corners, but is not limited thereto and may also have a rectangular shape with angled corners.

In embodiments, a first direction DR1 and a second direction DR2 may be different directions and intersect each other, for example, directions that intersect vertically in a plan view. In FIG. 1, the first direction DR1 may be generally the same as an extension direction of short sides of the display panel 100, and the second direction DR2 may be the same as an extension direction of long sides of the display panel 100. However, the directions described in the embodiments should be understood as indicating relative directions, and the embodiments are not limited to the described directions.

The display area DA may include short sides extending in the first direction DR1 and long sides extending in the second direction DR2. The non-display area NDA may surround the display area DA. The non-display area NDA may be disposed at one side and the other side of the display area DA in the first direction DR1 and one side and the other side of the display area DA in the second direction DR2.

The display panel 100 may further include a sensor non-display area NDA_S and sensor holes SH1 and SH2 surrounded by the sensor non-display area NDA_S. The sensor hole SH1 and SH2 may be surrounded by the display area DA in a plan view. The sensor hole SH1 and SH2 may be, for example, two sensor holes as in FIG. 1, but the embodiments of the inventive concepts are not limited thereto. For example, the sensor hole may be provided as one sensor hole. The two sensor holes SH1 and SH2 may each include a sensor hole in which an infrared sensor is disposed and a sensor hole in which a camera sensor is disposed, but the embodiments of the inventive concepts are not limited thereto. The sensor non-display area NDA_S may be disposed between the sensor holes SH1 and SH2 and the display area DA. The sensor non-display area NDA_S may completely surround the sensor holes SH1 and SH2. A pixel PX may not be disposed in the sensor non-display area NDA_S. In some embodiments, the sensor holes SH1 and SH2 are not disposed, and an infrared sensor or a camera sensor may be disposed in the display area DA. In this case, the number of pixels PX per area of the display area DA in which the infrared sensor or the camera sensor is disposed may be less than the number of pixels PX per area of the display area DA in which the infrared sensor or the camera sensor is not disposed. In particular, the display area DA in which the infrared sensor or the camera sensor is disposed may further include a transmissive area.

A gate driving unit GIP may be disposed in the non-display area NDA positioned at one side and the other side of the display area DA in the first direction DR1. A low potential voltage line VSSL may be disposed outside the gate driving unit GIP on the non-display area NDA. For example, as illustrated in FIG. 1, the low potential voltage line VSSL may extend from a printed circuit board FPCB, pass a sub-region SR and a bending region BR, may be positioned outside the gate driving unit GIP on the non-display area NDA, and disposed to surround the display area DA.

The non-display area NDA positioned at the other side of the display area DA in the second direction DR2 may extend further from a central portion of the other side toward the other side of the display area DA in the second direction DR2. A width of the non-display area NDA in the first direction DR1 further extending from the central portion of the other side toward the other side of the display area DA in the second direction DR2 may be smaller than a width of the non-display area NDA in the first direction DR1 adjacent to the other side of the display area DA in the second direction DR2.

The display device 1 may include a main region MR, the sub-region SR, and the bending region BR between the main region MR and the sub-region SR. The display area DA and the non-display area NDA surrounding four surfaces of the display area DA may form the main region MR, and a portion extending from the central portion of the other side toward the other side of the display area DA in the second direction DR2 may form the bending region BR and the sub-region SR. The bending region BR may be disposed between the sub-region SR and the main region MR. The sub-region SR may include a first pad area PA1 and a second pad area PA2 positioned at an end portion of the other side of the sub-region SR in the second direction DR2. The display device 1 may further include a data driving unit DIC and a printed circuit board FPCB. The data driving unit DIC may be disposed in the first pad area PA1, and the printed circuit board FPCB may be attached to the second pad area PA2. The data driving unit DIC may be configured, for example, in the form of a driving chip (IC), but is not limited thereto. In one embodiment, a case in which the data driving unit DIC is disposed by a chip on plastic method in which the data driving unit DIC is directly mounted on the display panel 100 is described, but the embodiments of the inventive concepts are not limited thereto, and the data driving unit DIC may be disposed by a chip on glass or chip on film method.

The display panel 100 according to one embodiment may further include a crack sensing pattern CSP surrounding the low potential voltage line VSSL. The crack sensing pattern CSP may be disposed to completely surround the display area DA as illustrated in FIG. 1. For example, the crack sensing pattern CSP may be disposed outside the low potential voltage line VSSL. However, the embodiments of the inventive concepts are not limited thereto, and a part of the crack sensing pattern CSP may not be disposed in the non-display area NDA of the other side of the display area DA in the second direction DR2.

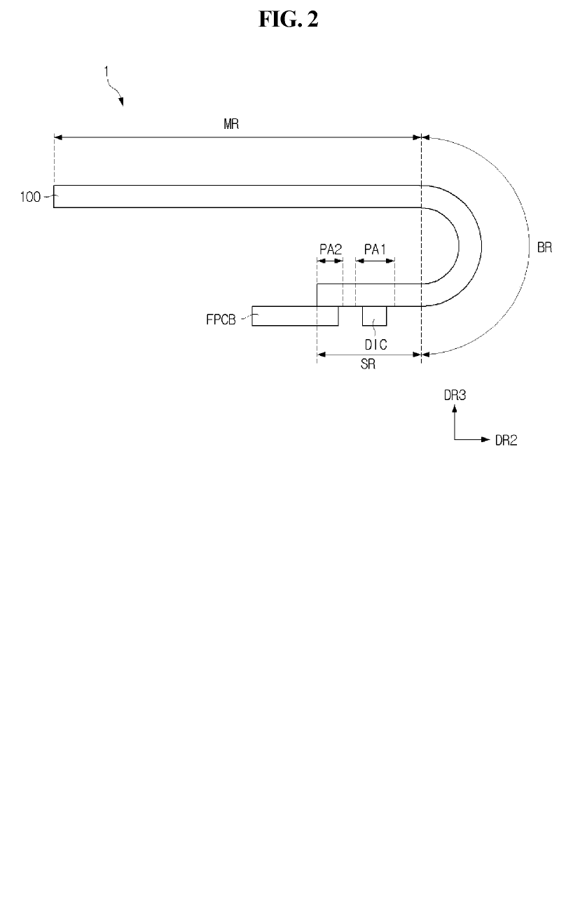

FIG. 2 is a side view illustrating a bent state of the display device according to FIG. 1.

Referring to FIG. 2, the bending region BR of the display panel 100 of the display device 1 according to one embodiment may be bent in a thickness direction (or a third direction DR3). Accordingly, the main region MR and the sub-region SR may overlap each other in the thickness direction. The display panel 100 may be bent in such a manner that a lower surface of the main region MR faces an upper surface of the sub-region SR. The printed circuit board FPCB may be attached to an end portion of the sub-region SR.

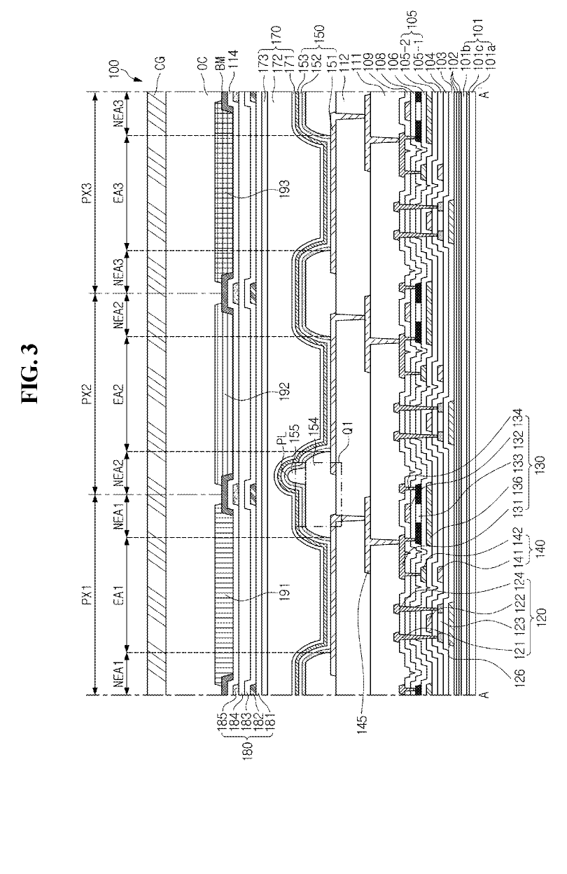

FIG. 3 is a cross-sectional view along line A-A’ shown in FIG. 1.

Referring to FIG. 3, the pixel PX (see FIG. 1) of the display panel 100 may include a plurality of sub-pixels PX1, PX2, and PX3. A first sub-pixel PX1 may be a red sub-pixel, a second sub-pixel PX2 may be a green sub-pixel, and a third sub pixel PX3 may be a blue sub-pixel, but the embodiments of the inventive concepts are not limited thereto. In some embodiments, the pixel PX may further include a fourth sub-pixel, and the fourth sub-pixel may be a white sub-pixel, but the embodiments of the inventive concepts are not limited thereto. In some embodiments, the pixel may include one red sub-pixel, two green sub-pixels, and one blue sub-pixel, but the embodiments of the inventive concepts are not limited thereto. For example, the plurality of sub-pixels PX1, PX2, and PX3 may be arranged in a stripe manner in the first direction DR1, but are not limited thereto, and may be arranged in a pentile manner.

The display panel 100 may include a substrate 101, a first thin film transistor 120, a second thin film transistor 130, a light-emitting part 150, an encapsulation part 170, a touch part 180, a filter insulating layer 114, a black matrix BM, color filters 191, 192, and 193, and a planarization layer OC. The display panel 100 may include at least one panel insulating layer and at least one touch insulating layer between the substrate 101 and the light-emitting part 150. The at least one panel insulating layer may include at least one of a buffer layer 102, a first insulating layer 103, a second insulating layer 104, a 3-1 insulating layer 105-1, a 3-2 insulating layer 105-2, a fourth insulating layer 106, a fifth insulating layer 108, a sixth insulating layer 109, a first protective layer 111, and a second protective layer 112, and the at least one touch insulating layer may include at least one of a touch buffer layer 181, a first touch insulating layer 183, and a second touch insulating layer 184.

The substrate 101 may include one or more plastic materials. For example, the substrate 101 may be a multi-substrate including a plurality of plastic materials, such as polyimide, etc. For example, the substrate 101 may include a first substrate portion 101a and a second substrate portion 101b each including a plastic material, and a third substrate portion 101c including an inorganic insulation material between the first substrate portion 101a and the second substrate portion 101b, but the embodiments of the inventive concepts are not limited thereto.

A buffer layer 102 may be disposed on the substrate 101. The buffer layer 102 may minimize or delay the diffusion of moisture or oxygen penetrating the substrate 101. The buffer layer 102 may be formed by alternately stacking silicon nitride (SiNₓ) and silicon oxide (SiOₓ) at least once, but the embodiments of the inventive concepts are not limited thereto.

A first light-shielding layer 126 may be disposed on the buffer layer 102. The first light-shielding layer 126 may prevent light from transmitting a first semiconductor layer 123 of the first thin film transistor 120. For example, the first semiconductor layer 123 may be disposed to overlap the first light-shielding layer 126. The first light-blocking layer 126 may be formed of a single layer or multiple layers formed of one of molybdenum (Mo), aluminum (Al), chromium (Cr), nickel (Ni), neodymium (Nd), and copper (Cu) or an alloy thereof, but the embodiments of the inventive concepts are not limited thereto.

The first insulating layer 103 may be disposed on the buffer layer 102 and the first light-shielding layer 126. The first insulating layer 103 may prevent a short circuit between a component of the first thin film transistor 120 and the first light-shielding layer 126. The first insulating layer 103 may be formed of the same material as the buffer layer 102, but the embodiments of the inventive concepts are not limited thereto. For example, the first insulating layer 103 may be formed of an inorganic insulation material, such as silicon nitride (SiNₓ) or silicon oxide (SiOₓ), but the embodiments of the inventive concepts are not limited thereto.

The first thin film transistor 120 may be disposed on the first insulating layer 103. The first thin film transistor 120 may include a first source electrode 121, a first gate electrode 122, the first semiconductor layer 123, and a first drain electrode 124.

The first semiconductor layer 123 may be disposed on the first insulating layer 103. The first semiconductor layer 123 may include a metal oxide semiconductor, such as indium-gallium-zinc oxide (IGZO), and a silicon-based semiconductor material, such as amorphous silicon, polycrystalline silicon, etc., but the embodiments of the inventive concepts are not limited thereto. The first semiconductor layer 123 may include a channel area, a source area, and a drain area.

Since the polycrystalline semiconductor layer has higher mobility than the amorphous semiconductor layer and the oxide semiconductor layer, power consumption may be less, and reliability may be excellent. Accordingly, a driving transistor may be formed of the polycrystalline semiconductor layer.

The second insulating layer 104 may be disposed on the first semiconductor layer 123. The second insulating layer 104 may be formed of the same material as the first insulating layer 103 and may prevent a short circuit between the first semiconductor layer 123 and another component of the first thin film transistor 120.

The first gate electrode 122 may be disposed on the second insulating layer 104. The first gate electrode 122 may be disposed on the second insulating layer 104 to overlap the channel area of the first semiconductor layer 123. The first gate electrode 122 may be formed of a single layer or multiple layers formed of molybdenum (Mo), copper (Cu), titanium (Ti), aluminum (Al), chromium (Cr), gold (Au), nickel (Ni), neodymium (Nd), or a compound thereof, but the embodiments of the inventive concepts are not limited thereto. The first gate electrode 122 may be disposed along with a gate line.

Third insulating layers 105-1 and 105-2 may be disposed on the first gate electrode 122. The third insulating layers 105-1 and 105-2 may be formed by alternately stacking silicon nitride (SiNₓ) and silicon oxide (SiOₓ) at least once, but the embodiments of the inventive concepts are not limited thereto. For example, a 3-1 insulating layer 105-1 may include silicon oxide (SiOₓ), and a 3-2 insulating layer 105-2 may include silicon nitride (SiNₓ), but the embodiments of the inventive concepts are not limited thereto.

The first source electrode 121 and the first drain electrode 124 may be disposed on the third insulating layers 105-1 and 105-2.

The first source electrode 121 and the first drain electrode 124 may be electrically connected to the first semiconductor layer 123 through contact holes. The first source electrode 121 and the first drain electrode 124 may be formed of a metallic material. For example, the first source electrode 121 and the first drain electrode 124 may be formed of a single layer or multiple layers formed of one of molybdenum (Mo), aluminum (Al), chromium (Cr), gold (Au), titanium (Ti), nickel (Ni), neodymium (Nd), and copper (Cu) or an alloy thereof, but the embodiments of the inventive concepts are not limited thereto.

The first source electrode 121 and the first drain electrode 124 may be disposed along with a data line. For example, the data line may be formed of the same material as the first source electrode 121 and the first drain electrode 124 and formed on the same layer as the first source electrode 121 and the first drain electrode 124, but the embodiments of the inventive concepts are not limited thereto.

A storage electrode 140 may be disposed to be spaced apart from the first thin film transistor 120. The storage electrode 140 may include a first storage electrode 141 and a second storage electrode 142.

The first storage electrode 141 may be formed of the same material as the first gate electrode 122 and disposed on the same layer as the first gate electrode 122, but the embodiments of the inventive concepts are not limited thereto.

The second storage electrode 142 may be disposed on the first storage electrode 141. The second storage electrode 142 may be disposed on the third insulating layers 105-1 and 105-2, and the third insulating layers 105-1 and 105-2 between the first storage electrode 141 and the second storage electrode 142 may be used as a dielectric to generate a capacitance. The second storage electrode 142 may be formed of the same material as the first storage electrode 141, but the embodiments of the inventive concepts are not limited thereto.

The second thin film transistor 130 may be disposed to be spaced apart from the first thin film transistor 120 and the storage electrode 140. The second thin film transistor 130 may include a second source electrode 131, a second gate electrode 132, a second semiconductor layer 133, and a second drain electrode 134.

A second light-shielding layer 136 may be disposed on the same layer as the second storage electrode 142.

The second light-shielding layer 136 may prevent light from traveling to the second semiconductor layer 133 similar to the first light-blocking layer 126, thereby extending the life of the second thin film transistor 130. For example, the second semiconductor layer 133 may be disposed to overlap the second light-shielding layer 136.

A fourth insulating layer 106 may be disposed on the second light-shielding layer 136. The fourth insulating layer 106 may be formed of the same material as the first insulating layer 103, the second insulating layer 104, or the third insulating layers 105-1 and 105-2, but the embodiments of the inventive concepts are not limited thereto.

The second semiconductor layer 133 may be disposed on the fourth insulating layer 106. The second semiconductor layer 133 may include a source area, a drain area, and a channel area between the source area and the drain area.

The second semiconductor layer 133 may include a metal oxide semiconductor, such as indium-gallium-zinc oxide (IGZO), and a silicon-based semiconductor material, such as amorphous silicon, polycrystalline silicon, etc., but the embodiments of the inventive concepts are not limited thereto.

A fifth insulating layer 108 may be disposed on the second semiconductor layer 133. The fifth insulating layer 108 may be formed of the same material as the first insulating layer 103, the second insulating layer 104, the third insulating layers 105-1 and 105-2, or the fourth insulating layer 106, but the embodiments of the inventive concepts are not limited thereto.

The second gate electrode 132 may be disposed on the fifth insulating layer 108.

The second gate electrode 132 may be formed of the same material as the first gate electrode 122. For example, the second gate electrode 132 may be formed of a single layer or multiple layers formed of molybdenum (Mo), copper (Cu), titanium (Ti), aluminum (Al), chromium (Cr), gold (Au), nickel (Ni), neodymium (Nd), or a compound thereof, but the embodiments of the inventive concepts are not limited thereto.

A sixth insulating layer 109 may be disposed on the second gate electrode 132. The sixth insulating layer 109 may be formed of the same material as the first insulating layer 103, the second insulating layer 104, the third insulating layers 105-1 and 105-2, the fourth insulating layer 106, or the fifth insulating layer 108, but the embodiments of the inventive concepts are not limited thereto.

The first source electrode 121, the first drain electrode 124, the second source electrode 131, and the second drain electrode 134 may be disposed on the sixth insulating layer 109.

The second source electrode 131 and the second drain electrode 134 may be formed of the same material as the first source electrode 121 and the first drain electrode 124 and disposed on the same layer as the first source electrode 121 and the first drain electrode 124, but the embodiments of the inventive concepts are not limited thereto. For example, the second source electrode 131 and the second drain electrode 134 may be formed of a single layer or multiple layers formed of any one of molybdenum (Mo), aluminum (Al), chromium (Cr), gold (Au), titanium (Ti), nickel (Ni), neodymium (Nd), and copper (Cu) or an alloy thereof, but the embodiments of the inventive concepts are not limited thereto. For example, the second source electrode 131 may be electrically connected to the second storage electrode 142. The second source electrode 131 may pass through the sixth insulating layer 109, the fifth insulating layer 108, and the fourth insulating layer 106 and may be electrically connected to the second storage electrode 142.

A first protective layer 111 may be disposed on the first source electrode 121 and the first drain electrode 124.

The first protective layer 111 may planarize an upper portion of the first thin film transistor 120 and protect the first thin film transistor 120. The first protective layer 111 may be formed of an organic material. For example, the first protective layer 111 may be formed of an organic material including an acrylic resin, an epoxy resin, a phenolic resin, a polyamide resin, or a polyimide resin, but the embodiments of the inventive concepts are not limited thereto.

A second protective layer 112 may be disposed on the first protective layer 111. The second protective layer 112 may be formed of the same material as the first protective layer 111, but the embodiments of the inventive concepts are not limited thereto.

In some embodiments, a third protective layer may be further disposed on an upper surface of the second protective layer 112, but the embodiments of the inventive concepts are not limited thereto.

A connection electrode 145 may be disposed between the first protective layer 111 and the second protective layer 112.

The connection electrode 145 may electrically connect the first thin film transistor 120 to the light-emitting part 150. The connection electrode 145 may be formed of the same material as the first source electrode 121 and the first drain electrode 124, but the embodiments of the inventive concepts are not limited thereto.

The connection electrode 145 may be formed of a single layer or multiple layers formed of one of molybdenum (Mo), aluminum (Al), chromium (Cr), gold (Au), titanium (Ti), nickel (Ni), neodymium (Nd), and copper (Cu) or an alloy thereof, but the embodiments of the inventive concepts are not limited thereto.

The light-emitting part 150 may be disposed on the second protective layer 112. The light-emitting part 150 may include a first electrode 151, an organic layer 152, and a second electrode 153. The first electrode 151 may serve as an anode, and the second electrode 153 may serve as a cathode.

The first electrode 151 may be disposed on the second protective layer 112. The first electrode 151 may be electrically connected to the first thin film transistor 120 through a contact hole formed in the second protective layer 112. The first electrode 151 may be a reflective electrode that reflects light, but the embodiments of the inventive concepts are not limited thereto. The first electrode 151 may include a metallic material with high reflectance, such as a stacking structure (Ti/Al/Ti) of aluminum (Al) and titanium (Ti), a stacking structure (ITO/Al/ITO) of aluminum (Al) and indium tin oxide (ITO), or an APC alloy and may be formed of a single layer or multiple layers, but the embodiments of the inventive concepts are not limited thereto.

The organic layer 152 may be disposed on the first electrode 151. The organic layer 152 may include one or more light-emitting structures (or light-emitting elements or elements) stacked on the first electrode 151 in the order or reverse order of a hole transfer layer and an electron transfer layer. For example, the hole transfer layer may include a hole transporting layer, a hole injecting layer, an electron blocking layer, a p-type charge generation layer, etc., but the embodiments of the inventive concepts are not limited thereto. For example, the electron transfer layer may include an electron transporting layer, an electron injecting layer, a hole blocking layer, an n-type charge generation layer, etc., but the embodiments of the inventive concepts are not limited thereto. The organic layer 152 may be an organic light-emitting layer, an inorganic light-emitting layer, a quantum dot light-emitting layer, a micro light-emitting diode, a micro mini light-emitting diode, etc., but the embodiments of the inventive concepts are not limited thereto. For example, the organic layer 152 of the display panel 100 according to one embodiment of the inventive concepts may include an organic light-emitting layer. The organic layer 152 may include a red light-emitting layer, a green light-emitting layer, and a blue light-emitting layer. The organic layer 152 may be a white light-emitting layer, but the embodiments of the inventive concepts are not limited thereto. Hereinafter, a specific structure of the organic layer 152 according to one embodiment will be described.

The second electrode 153 may be disposed on the organic layer 152. The second electrode 153 may be a transparent electrode that transmits light, but the embodiments of the inventive concepts are not limited thereto. For example, the second electrode 153 may include a transparent conductive material, such as indium tin oxide (ITO) or indium zinc oxide (IZO), or a metal that transmits visible light, but the embodiments of the inventive concepts are not limited thereto.

A bank 154 may be disposed to expose the first electrode 151. The bank 154 may define openings (or light-emitting areas EA1, EA2, and EA3) of the sub-pixels PX1, PX2, and PX3 and may be disposed to cover an edge portion (or a periphery) of the first electrode 151. In particular, the first sub-pixel PX1 may include a first light-emitting area EA1 and a first non-light-emitting area NEA1 around the first light-emitting area EA1, the second sub-pixel PX2 may include a second light-emitting area EA2 and a second non-light-emitting area NEA2 around the second light-emitting area EA2, and the third sub-pixel PX3 may include a third light-emitting area EA3 and a third non-light-emitting area NEA3 around the third light-emitting area EA3. In particular, the non-light-emitting area NEA1, NEA2, and NEA3 may correspond one-to-one to boundaries between adjacent sub-pixels PX1, PX2, and PX3.

The bank 154 may include a black-based material. For example, the bank 154 may be formed of a material containing black pigment, or an organic material, such as a benzocyclobutene resin, a polyimide resin, an acrylic resin, a photosensitive polymer, etc., but the embodiments of the inventive concepts are not limited thereto. When the bank 154 is formed of a material containing black pigment or black dye, the bank 154 may be a black bank. When the bank 154 is formed of a material containing black pigment or black dye, it is possible to block external light or light reflected from the outside, thereby further increasing the luminance of the display device.

Although not illustrated, a barrier may be further disposed on the bank 154. The barrier may be disposed directly on an upper surface of the bank 154, but the embodiments of the inventive concepts are not limited thereto. The barrier may serve to separate the organic layer 152 from the boundaries of adjacent sub-pixels PX1, PX2, and PX3. In some embodiments, the barrier may be omitted, and a trench may be formed in the bank 154. The trench may recess the bank 154 in the thickness direction.

A spacer 155 may be further disposed on the bank 154. The spacer 155 may be formed of the same material as the bank 154, but the embodiments of the inventive concepts are not limited thereto. For example, the spacer 155 may be a transparent bank, but is not limited thereto, and the spacer 155 may be formed of the same material as the bank 154. For example, the spacer 155 may be disposed on at least one of the boundaries of the first to third sub-pixels PX1, PX2, and PX3, but the embodiments of the inventive concepts are not limited thereto.

The display panel 100 according to one embodiment may further include an optical inorganic layer PL that covers (or overlaps) the bank 154. As illustrated in FIG. 3, the optical inorganic layer PL may be in direct contact with the upper surface and inner surface of the bank 154. The optical inorganic layer PL may be disposed in the non-light-emitting areas NEA1, NEA2, and NEA3, but may also be disposed in some of the light-emitting areas EA1, EA2, and EA3. The optical inorganic layer PL may cover (or overlap) the spacer 155 and may also be in contact with an upper surface and side surfaces of the spacer 155. In the light-emitting areas EA1, EA2, and EA3, the optical inorganic layer PL may be in direct contact with an upper surface of the first electrode 151. The optical inorganic layer PL may expose a central portion of the first electrode 151. The optical inorganic layer PL may be a porous inorganic layer. A plurality of pores (or air layers) may be disposed inside the optical inorganic layer PL. A refractive index of the optical inorganic layer PL may be lower than a refractive index of the bank 154. The optical inorganic layer PL will be described in detail below.

The organic layer 152 may be disposed on the first electrode 151, the bank 154, and the spacer 155. The second electrode 153 may be disposed on the organic layer 152. The organic layer 152 may be disposed on the optical inorganic layer PL. The organic layer 152 may be in direct contact with the central portion of the first electrode 151 exposed by the optical inorganic layer PL. According to an embodiment of the inventive concepts, the organic layer 152 may be disposed over the entire surface of the first sub-pixel PX1, the second sub-pixel PX2, and the third sub-pixel PX3. In this case, the organic layer 152 may emit white light from each of the sub-pixels PX1, PX2, and PX3.

In some embodiments, although not illustrated, the organic layer 152 may include a first organic layer 152a disposed in the first sub-pixel PX1, a second organic layer 152b disposed in the second sub-pixel PX2, and a third organic layer 152c disposed in the third sub-pixel PX3. In particular, the organic layers disposed in each of the sub-pixels PX1, PX2, and PX3 may be physically separated. The organic layers disposed in each of the sub-pixels PX1, PX2, and PX3 may be disposed on the upper surface of the first electrode 151 and may overlap lower end portions of the side surfaces of the bank 154, but the embodiments of the inventive concepts are not limited thereto, and may also overlap upper end portions of the side surfaces of the bank 154 or the upper surface of the bank 154.

The encapsulation part 170 may be disposed on the second electrode 153. The encapsulation part 170 may include one or more insulating layers. For example, the encapsulation part 170 may include a first encapsulation layer 171, a second encapsulation layer 172 disposed on the first encapsulation layer 171, and a third encapsulation layer 173 disposed on the second encapsulation layer 172. The encapsulation part 170 may include one or more inorganic insulation material layers and one or more organic material layers. For example, the first encapsulation layer 171 and the third encapsulation layer 173 may include an inorganic insulation material, and the second encapsulation layer 172 may include an organic material, but the embodiments of the inventive concepts are not limited thereto.

The touch part 180 may be disposed on the encapsulation part 170. The touch part 180 may include the touch buffer layer 181, a first touch conductive layer, the first touch insulating layer 183, the second touch insulating layer 184, and a second touch conductive layer. In some embodiments, one or more touch organic layers may be further disposed on the second touch conductive layer, but the embodiments of the inventive concepts are not limited thereto.

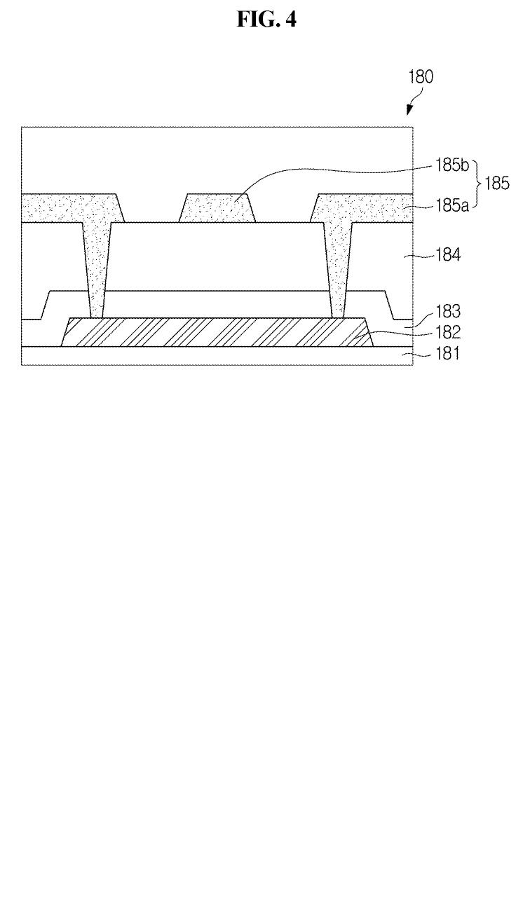

FIG. 4 is a cross-sectional view of a touch part according to FIG. 3.

Referring to FIGS. 3 and 4, the touch buffer layer 181 may be disposed on the encapsulation part 170. For example, the touch buffer layer 181 may be disposed on the third encapsulation layer 173. The touch buffer layer 181 may be formed of the same material as the buffer layer 102, but the embodiments of the inventive concepts are not limited thereto.

A first touch conductive layer may be disposed on the touch buffer layer 181. The first touch conductive layer may include a bridge electrode 182. The bridge electrode 182 and a sensor electrode 185 to be described below may be disposed at each of the boundaries between adjacent sub-pixels PX1, PX2, and PX3. For example, the bridge electrode 182 and the sensor electrode 185 may be disposed in the non-light-emitting areas NEA1, NEA2, and NEA3. The bridge electrode 182 and the sensor electrode 185 may overlap the black matrix BM to be described below in the thickness direction. The black matrix BM may cover the bridge electrode 182 and the sensor electrode 185. Accordingly, the bridge electrode 182 and the sensor electrode 185 may be prevented from being visible from the outside.

The first touch insulating layer 183 and the second touch insulating layer 184 disposed on the first touch insulating layer 183 may be disposed on the first touch conductive layer. The first touch insulating layer 183 and the second touch insulating layer 184 disposed on the first touch insulating layer 183 may prevent a short circuit between the first touch conductive layer and the second touch conductive layer. The first touch insulating layer 183 may be formed of silicon oxide (SiOₓ), silicon nitride (SiNₓ), or multiple layers thereof, but the embodiments of the inventive concepts are not limited thereto. The second touch insulating layer 184 may include an organic insulation material, but the embodiments of the inventive concepts are not limited thereto, and the second touch insulating layer 184 may include the same material as the first touch insulating layer 183.

The second touch conductive layer may be disposed on the second touch insulating layer 184. The second touch conductive layer may include a first sensor electrode 185a and a second sensor electrode 185b. The sensor electrode 185 may include the first sensor electrode 185a extending in the first direction DR1 (see FIG. 1) and the second sensor electrode 185b extending in the second direction DR2 (see FIG. 1) different from the first direction DR1.

The bridge electrode 182 may be electrically connected to the first sensor electrode 185a through a contact hole formed in the first touch insulating layer 183 and the second touch insulating layer 184. For example, the first sensor electrode 185a and the bridge electrode 182 may extend in the first direction DR1 (see FIG. 1).

The sensor electrode 185 and the bridge electrode 182 may include a metallic material. For example, the first touch conductive layer may be formed of titanium (Ti), nickel (Ni), aluminum (Al), or an alloy thereof and formed of a triple layer, such as titanium (Ti)/aluminum (Al)/titanium (Ti), but the embodiments of the inventive concepts are not limited thereto.

The filter insulating layer 114 may be disposed on the second touch conductive layer. The filter insulating layer 114 may be formed of an inorganic insulation material, such as silicon nitride (SiNₓ) or silicon oxide (SiOₓ), but the embodiments of the inventive concepts are not limited thereto.

The black matrix BM may be disposed on the filter insulating layer 114. The black matrix BM may include a black-based material. For example, the black matrix BM may include a light-blocking material or a light-absorbing material. For example, the black matrix BM may be formed of a material including a black pigment, a black dye, etc. The black matrix BM may cover the bridge electrode 182 and the sensor electrode 185. Accordingly, the bridge electrode 182 and the sensor electrode 185 may be prevented from being visible from the outside. For example, a width of the black matrix BM may be smaller than a width of the bank 154.

For example, spacing distances between an end of the black matrix BM and boundaries between the light-emitting areas EA1, EA2, and EA3 and the non-light-emitting areas NEA1, NEA2, and NEA3 may be longer than spacing distances between an end of the bank 154 and the boundaries between the light-emitting areas EA1, EA2, and EA3 and the non-light-emitting areas NEA1, NEA2, and NEA3. The end of the bank 154 may be aligned with the boundaries between the light-emitting areas EA1, EA2, and EA3 and the non-light-emitting areas NEA1, NEA2, and NEA3, but the embodiments of the inventive concepts are not limited thereto. In the case of the display panel 100 according to one embodiment, since the bank 154 may include a black-based material and the spacing distances between an end of the black matrix BM and boundaries between the light-emitting areas EA1, EA2, and EA3 and the non-light-emitting areas NEA1, NEA2, and NEA3 may be longer than spacing distances between an end of the bank 154 and the boundaries between the light-emitting areas EA1, EA2, and EA3 and the non-light-emitting areas NEA1, NEA2, and NEA3, light emitted from the light-emitting areas EA1, EA2, and EA3 may be emitted upward with a greater viewing angle as much as a spacing space between the end of the black matrix BM and the boundaries between the light-emitting areas EA1, EA2, and EA3 and the non-light-emitting areas NEA1, NEA2, and NEA3. Accordingly, it is possible to minimize a reduction in luminance according to a viewing angle. However, when the spacing distances between the end of the black matrix BM and the boundaries between the light-emitting areas EA1, EA2, and EA3 and the non-light-emitting areas NEA1, NEA2, and NEA3 may be longer than the spacing distances between the end of the bank 154 and the boundaries between the light-emitting areas EA1, EA2, and EA3 and the non-light-emitting areas NEA1, NEA2, and NEA3 and the bank 154 is formed of only a transparent material, externally incident light may be reflected by the bank 154, resulting in visible ring-shaped spots. However, in the case of the display panel 100 according to one embodiment, the light incident from the outside may be absorbed or blocked by the bank 154 including a black-based material, thereby preventing the occurrence of the ring-shaped spots.

The color filters 191, 192, and 193 may be disposed on the black matrix BM. The color filters 191, 192, and 193 may be disposed on the first to third sub-pixels PX1, PX2, and PX3, respectively, and may block specific colors from light emitted from the light-emitting area EA1, EA2, and EA3 of the sub-pixels PX1, PX2, and PX3. A first color filter 191 may be provided to block light of other colors not including red (R) light. In this case, the first color filter 191 may be provided as a red color filter. A second color filter 192 may be provided to block light of other colors not including green (G) light. In this case, a second color filter 192 may be provided as a green color filter. A third color filter 193 provided in the third sub-pixel PX3 may be provided to block light of other colors not including blue (B) light. In this case, the third color filter 193 may be provided as a blue color filter. However, the embodiments of the inventive concepts are not limited thereto.

For example, each of the color filters 191, 192, and 193 may come into direct contact with side and upper surfaces of the black matrix BM. For example, each of the color filters 191, 192, and 193 may be spaced apart from the boundaries of adjacent sub-pixels PX1, PX2, and PX3, but the embodiments of the inventive concepts are not limited thereto, and the color filters 191, 192, and 193 may overlap each other in the thickness direction.

The planarization layer OC may be disposed on the color filters 191, 192, and 193. The planarization layer OC may serve to planarize a step formed by the color filters 191, 192, and 193. For example, the planarization layer OC may include an organic insulation material.

A cover layer CG may be disposed on the planarization layer OC. The cover layer CG may be formed of a glass material including glass, quartz, etc., but the embodiments of the inventive concepts are not limited thereto, and the cover layer CG may be formed of a plastic material. The cover layer CG may be disposed above the display panel 100 to protect members disposed under the cover layer CG from the outside. The cover layer CG may be a cover layer formed by chemical reinforcement, but the embodiments of the inventive concepts are not limited thereto. The cover layer CG may be a cover window, a window cover, or a cover member, but the embodiments of the inventive concepts are not limited thereto. The embodiments of the inventive concepts are not limited thereto.

An anti-reflective layer capable of reducing the reflectance of external light may be additionally disposed on the cover layer CG, but the embodiments of the inventive concepts are not limited thereto.

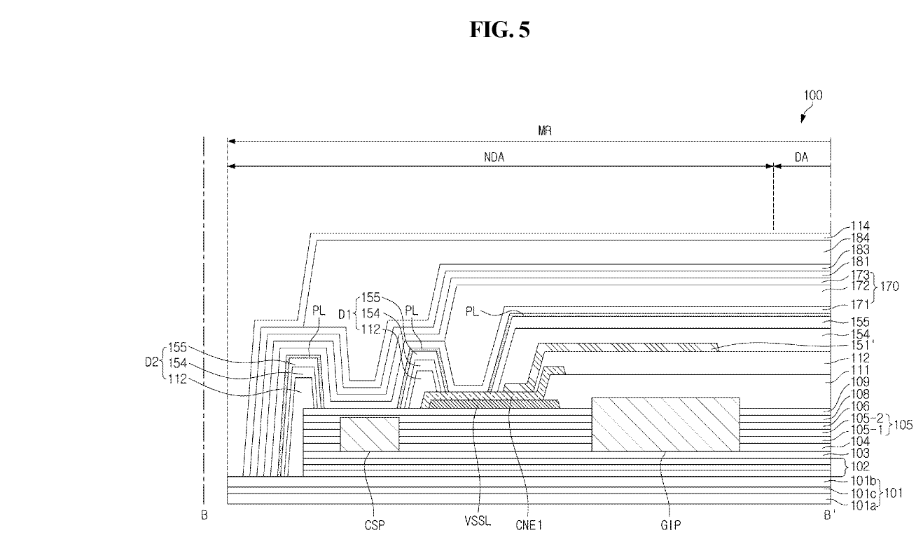

FIG. 5 is a cross-sectional view along line B-B’ in FIG. 1.

Referring to FIG. 5, at least one of the panel inorganic layers 102, 103, 104, 105-1, 105-2, 106, 108, and 109 may not extend to an end of the substrate 101. In particular, the at least one of the panel inorganic layers 102, 103, 104, 105-1, 105-2, 106, 108, and 109 may expose the end of the substrate 101, but the embodiments of the inventive concepts are not limited thereto.

The display panel 100 according to one embodiment may further include the crack sensing pattern CSP, the low potential voltage line VSSL, and the gate driving unit GIP. As described above in FIG. 1, the low potential voltage line VSSL may be positioned between the crack sensing pattern CSP and the display area DA, and the gate driving unit GIP may be positioned between the low potential voltage line VSSL and the display area DA.

For example, the gate driving unit GIP may be formed of a conductive layer positioned on the same layer as the first gate electrode 122 (see FIG. 3), a conductive layer positioned on the same layer as the second light-shielding layer 136 (see FIG. 3), or a conductive layer positioned on the same layer as the first source electrode 121, but the embodiments of the inventive concepts are not limited thereto.

For example, the crack sensing pattern CSP may be disposed between a first dam D1 and a second dam D2. The crack sensing pattern CSP may be formed of a conductive layer disposed on the same layer as the first gate electrode 122 (see FIG. 3) or a conductive layer disposed on the same layer as the second light-shielding layer 136 (see FIG. 3), but the embodiments of the inventive concepts are not limited thereto. For example, the crack sensing pattern CSP may include a conductive layer disposed on the same layer as the first source electrode 121, but the embodiments of the inventive concepts are not limited thereto.

The low potential voltage line VSSL may be disposed between the crack sensing pattern CSP and the gate driving unit GIP. The low potential voltage line VSSL may be formed of a conductive layer disposed on the same layer as the first source electrode 121, but the embodiments of the inventive concepts are not limited thereto.

The first protective layer 111 may cover the gate driving unit GIP, partially cover one end portion of the low potential voltage line VSSL, and expose the other end portion of the low potential voltage line VSSL. In the inventive concepts, the one end portion may refer to an area of a certain component, which is disposed in a direction from the non-display area NDA toward the display area DA, and the other end portion may refer to an area of the certain component, which is disposed in a direction from the display area DA toward the non-display area NDA.

A first connection electrode CNE1 disposed on the same layer as the connection electrode 145 may be disposed on the first protective layer 111. The first connection electrode CNE1 may be directly connected to an area of the low potential voltage line VSSL, in which the first protective layer 111 is exposed. The first connection electrode CNE1 may cover the other end portion of the low potential voltage line VSSL, but the embodiments of the inventive concepts are not limited thereto.

The second protective layer 112 may be disposed on the first connection electrode CNE1. The second protective layer 112 may come into direct contact with and cover one end portion of the first connection electrode CNE1 and expose the other end portion of the first connecting electrode CNE1. The second protective layer 112 may form a first layer of a first dam D1 and a first layer of a second dam D2. The second dam D2 may overlap, for example, the low potential voltage line VSSL and cover the other end portion of the low potential voltage line VSSL. The second dam D2 may come into direct contact with the first connection electrode CNE1 and cover the other end portion of the first connection electrode CNE1. The second protective layer 112 forming the first layer of the first dam D1 may come into direct contact with the exposed side surfaces of at least one of the panel inorganic layers 102, 103, 104, 105, 106, 107, and 109 and may come into direct contact with an upper surface of the substrate 101, but the embodiments of the inventive concepts are not limited thereto. The second protective layer 112 may overlap the gate driving unit GIP. In the inventive concepts, the dam is, for example, provided as two dams, but the dam may be provided as three or more dams or one dam.

A low potential connection electrode 151’ disposed on the same layer as the first electrode 151 (see FIG. 3) may be disposed on the first connection electrode CNE1 exposed by the second protective layer 112 and the second protective layer 112. The low potential connection electrode 151’ may be electrically connected to the first connection electrode CNE1 exposed by the second protective layer 112. The low potential connection electrode 151’ may be electrically connected to the second electrode 153 (see FIG. 3) described above in FIG. 3.

The bank 154 may be disposed on the low potential connection electrode 151’ and the second protective layer 112. The bank 154 may overlap the gate driving unit GIP, overlap the low potential connection electrode 151’, and cover the other end portion of the low potential connection electrode 151’. The bank 154 may completely cover the low potential connection electrode 151’, but the embodiments of the inventive concepts are not limited thereto. The bank 154 may expose a central portion and the other end portion of the first connection electrode CNE1, but the embodiments of the inventive concepts are not limited thereto. The bank 154 may form a second layer of the first dam D1 and a second layer of the second dam D2. In each dam D1 or D2, the bank 154 may overlap the second protective layer 112 forming the first layer and completely cover the second protective layer 112, but the embodiments of the inventive concepts are not limited thereto. In the second dam D2, the bank 154 may come into contact with the side surfaces of the second protective layer 112 and the upper surface of the substrate 101, but the embodiments of the inventive concepts are not limited thereto.

The spacer 155 may be disposed on the bank 154. The spacer 155 may overlap the gate driving unit GIP. The spacer 155 may form a third layer of the dams D1 and D2. The spacer 155 forming the third layer of each dam D1 or D2 may overlap the bank 154 forming the second layer and completely cover the bank 154, but the embodiments of the inventive concepts are not limited thereto. In the second dam D2, the spacer 155 may come into contact with the side surfaces of the bank 154 and the upper surface of the substrate 101, but the embodiments of the inventive concepts are not limited thereto.

The optical inorganic layer PL may be disposed on the spacer 155. The optical inorganic layer PL may overlap each of the dams D1 and D2 and cover the spacer 155 forming the third layer of each of the dams D1 and D2. The optical inorganic layer PL may be in direct contact with upper and side surfaces of each of the dams D1 and D2. The optical inorganic layer PL may be in direct contact with the upper and side surfaces of the spacer 155 in the non-display area NDA. The optical inorganic layer PL disposed on the first dam D1 may be in direct contact with an upper surface of the first connection electrode CNE1 and an upper surface of the sixth insulating layer 109. The optical inorganic layer PL disposed on the second dam D2 may be in direct contact with the upper surface of the sixth insulating layer 109 and the upper surface of the substrate portion 101, but the embodiments of the inventive concepts are not limited thereto.

As illustrated in FIG. 5, the optical inorganic layer PL may cover the dams D1 and D2 in the non-display area NDA, thereby blocking, delaying, or reducing moisture penetration from the outside into the display area DA.

FIG. 5 illustrates the optical inorganic layer PL disposed in only the area in which the spacer 155 is disposed. In particular, the optical inorganic layer PL may be formed using the same mask as the mask for forming the spacer 155 or the bank 154. However, the embodiments of the inventive concepts are not limited thereto, and the optical inorganic layer PL may be disposed over the entire non-display area NDA illustrated in FIG. 5.

The encapsulation part 170 may be disposed on the spacer 155 and the optical inorganic layer PL. The first encapsulation layer 171 may extend to the gate driving unit GIP, the low potential voltage line VSSL, the first dam D1, and the second dam D2 and cover an outer surface of the second dam D2. At least a portion of the first encapsulation layer 171 may be in direct contact with an upper surface of the optical inorganic layer PL. The second encapsulation layer 172 may end at the first dam D1. The second encapsulation layer 172 may overlap the gate driving unit GIP and the low potential voltage line VSSL. The third encapsulation layer 173 may extend to the gate driving unit GIP, the low potential voltage line VSSL, the first dam D1, and the second dam D2 and come into direct contact with the first encapsulation layer 171 on the first dam D1, the crack sensing pattern CSP, and the second dam D2.

The touch buffer layer 181 and the first touch insulating layer 183 may extend to the gate driving unit GIP, the low potential voltage line VSSL, the first dam D1, and the second dam D2 and cover the outer surface of the second dam D2. The second touch insulating layer 184 may extend to the gate driving unit GIP, the low potential voltage line VSSL, the first dam D1, and the crack sensing pattern CSP and end on the second dam D2, but the embodiments of the inventive concepts are not limited thereto.

The filter insulating layer 114 may extend to the gate driving unit GIP, the low potential voltage line VSSL, the first dam D1, and the second dam D2 and come into direct contact with an outer surface of the second touch insulating layer 184, but the embodiments of the inventive concepts are not limited thereto.

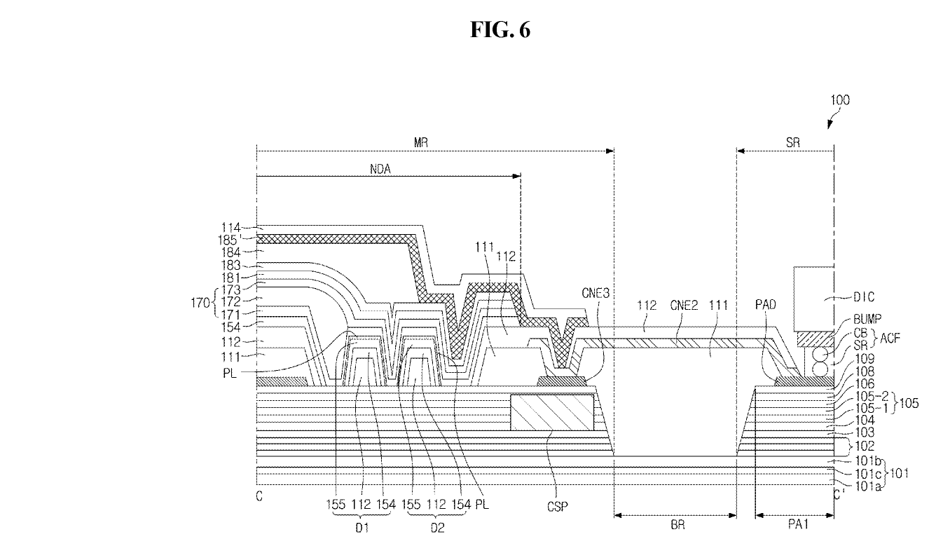

FIG. 6 is a cross-sectional view along line C-C’ in FIG. 1.

Referring to FIGS. 3, 5, and 6, the bending region BR may be disposed between the sub-region SR and the crack sensing pattern CSP. In the bending region BR, the panel inorganic layers 102, 103, 104, 105, 106, 107, and 109 may be removed to expose the upper surface of the substrate 101.

In the first pad area PA1, a pad electrode PAD disposed on the same layer as the first source electrode 121 (see FIG. 3) may be disposed, and a third connection electrode CNE3 disposed on the same layer as the first source electrode 121 (see FIG. 3) may be disposed on the crack sensing pattern CSP.

The first protective layer 111 may be disposed on the pad electrode PAD and the third connection electrode CNE3. The first protective layer 111 may be disposed in the bending region BR, and the first protective layer 111 may come into direct contact with the upper surface of the substrate 101 and in the bending region BR, the first protective layer 111 may come into direct contact with the side surfaces of the panel inorganic layers 102, 103, 104, 105, 106, 107, and 109.

A second connection electrode CNE2 may be disposed on the first protective layer 111, and the second connection electrode CNE2 may be disposed on the same layer as the connection electrode 145 (see FIG. 3). The second connection electrode CNE2 may electrically connect the pad electrode PAD to the third connection electrode CNE3. The second connection electrode CNE2 may be disposed on the bending region BR and may also be disposed on the first pad area PA1 and the crack sensing pattern CSP.

The data driving unit DIC may be disposed on the pad electrode PAD. The data driving unit DIC may include a bump BUMP, an anisotropic conductive film ACF may be disposed between the pad electrode PAD and the bump BUMP, and the anisotropic conductive film ACF may electrically connect the pad electrode PAD to the bump BUMP. The anisotropic conductive film ACF may include a resin SR and a plurality of conductive balls CB dispersed in the resin SR. The pad electrode PAD and the bump BUMP may be electrically connected through the conductive balls CB.

The second protective layer 112 may be disposed on the second connection electrode CNE2. The second protective layer 112 may expose the pad electrode PAD.

The first and second encapsulation layers 171 and 173 of the encapsulation part 170 may extend until before the bending region BR. For example, the first and second encapsulation layers 171 and 173 may extend until before the crack sensing pattern CSP, but the embodiments of the inventive concepts are not limited thereto, and the first and second encapsulation layers 171 and 173 may also overlap the crack sensing pattern CSP. The first and second encapsulation layers 171 and 173 may not be disposed in the bending region BR.

The touch buffer layer 181 and the first touch insulating layer 183 may extend until before the bending region BR. For example, the touch buffer layer 181 and the first touch insulating layer 183 may extend until before the crack sensing pattern CSP, but the embodiments of the inventive concepts are not limited thereto, and the touch buffer layer 181 and the first touch insulating layer 183 may also overlap the crack sensing pattern CSP. The touch buffer layer 181 and the first touch insulating layer 183 may not be disposed in the bending region BR.

The second touch insulating layer 184 may overlap the first dam D1 and the second dam D2. The second touch insulating layer 184 may not be disposed outside the second dam D2, but the embodiments of the inventive concepts are not limited thereto.

A touch connection line 185’ may be electrically connected to the second connection electrode CNE2. The touch connection line 185’ may serve to provide a signal applied from the pad electrode PAD and the second connection electrode CNE2 to the first sensor electrode 185a or the second sensor electrode 185b described above in FIG. 4. The touch connection line 185’ may be disposed on the same layer as the second touch conductive layer (the first sensor electrode 185a of FIG. 4), but the embodiments of the inventive concepts are not limited thereto, and the touch connection line 185’ may be disposed on the same layer as the first touch conductive layer (the bridge electrode 182 of FIG. 3) or formed of two first and second touch conductive layers, but the embodiments of the inventive concepts are not limited thereto.

The filter insulating layer 114 may be disposed on the touch connection line 185’, and the filter insulating layer 114 may not be disposed in the bending region BR.

The optical inorganic layer PL may be disposed on the spacer 155. The optical inorganic layer PL may overlap each of the dams D1 and D2 and cover the spacer 155 forming the third layer of each of the dams D1 and D2. The optical inorganic layer PL may be in direct contact with upper and side surfaces of each of the dams D1 and D2. The optical inorganic layer PL may be in direct contact with the upper and side surfaces of the spacer 155 in the non-display area NDA. The optical inorganic layer PL disposed on the first dam D1 may be in direct contact with the upper surface of the sixth insulating layer 109. The optical inorganic layer PL disposed on the second dam D2 may be in direct contact with the upper surface of the sixth insulating layer 106.

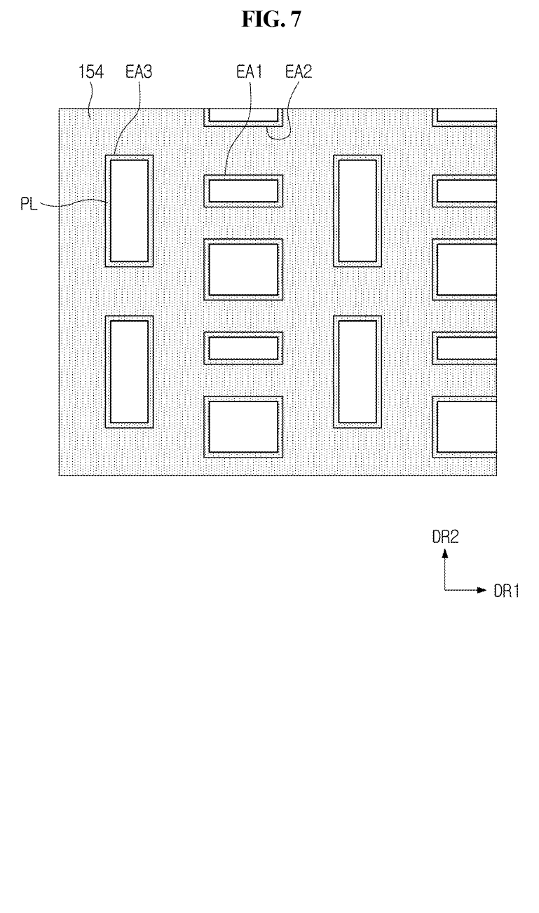

FIG. 7 is a plan view of a display panel according to one embodiment. FIG. 7 illustrates the light-emitting areas EA1, EA2, and EA3, the bank 154, and the optical inorganic layer PL. As described above in FIG. 3, the bank 154 may include an opening, and the light-emitting areas EA1, EA2, and EA3 may be disposed within the opening of the bank 154. As described above in FIG. 3, the optical inorganic layer PL may also be partially disposed in the light-emitting areas EA1, EA2, and EA3.

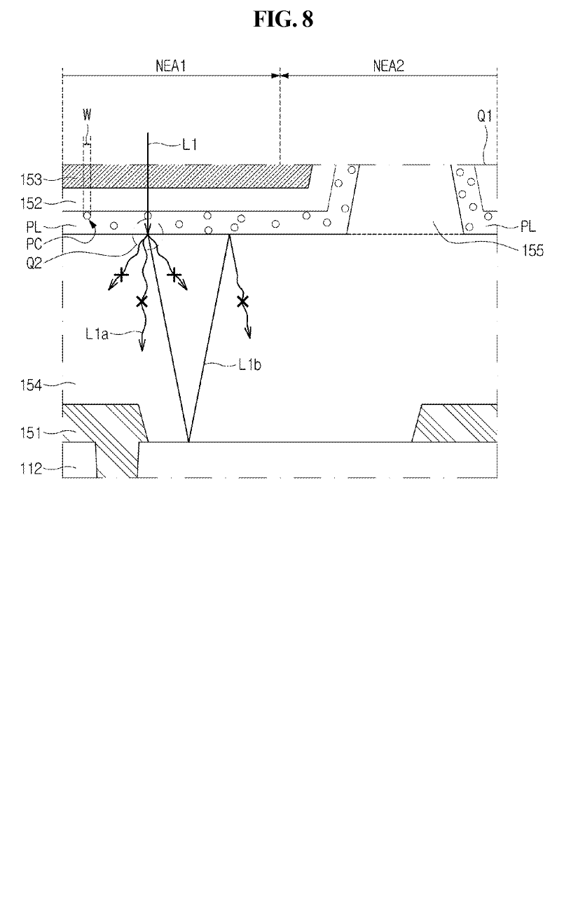

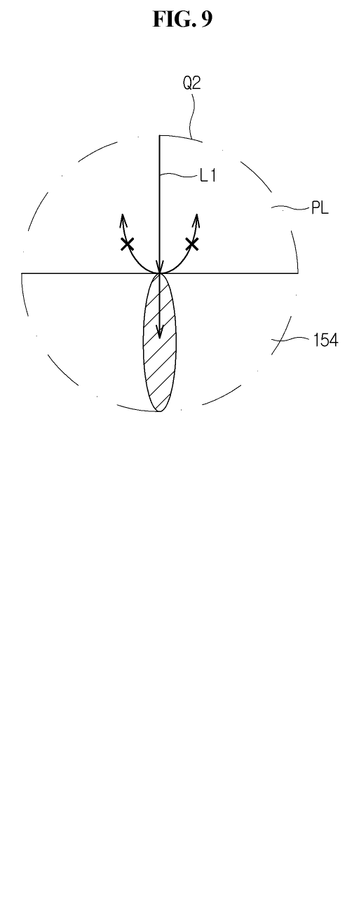

FIG. 8 is an enlarged cross-sectional view of area Q1 in FIG. 3. FIG. 9 is an enlarged cross-sectional view of area Q2 in FIG. 8.

Referring to FIGS. 8 and 9, a plurality of pores (or air) may be disposed inside the optical inorganic layer PL. The optical inorganic layer PL may be a porous inorganic layer. The refractive index of the optical inorganic layer PL may be lower than the refractive index of the bank 154. A diameter W (or a size) of the pore PC may be designed to allow light L1 passing through the organic layer 152 to enter the bank 154. For example, the diameter W of the pore PC may be about 0.3 μm or more. As illustrated in FIGS. 8 and 9, the pore PC inside the optical inorganic layer PL according to one embodiment needs to allow the light L1 to travel to the bank 154 at an interface between the optical inorganic layer PL and the bank 154. For example, when the diameter W of the pore PC is less than about 0.3 μm (Rayleigh scattering, which exhibits a high scattering rate in all directions), the light L1 entering the pore PC may travel to the bank 154, but may also be more likely to be reflected and travel to the organic layer 152. On the other hand, when the diameter W of the pore PC is greater than about 0.3 μm (Mie scattering, which exhibits a high scattering rate in one direction), the light L1 entering the pore PC may be very unlikely to be reflected and travel to the organic layer 152.

The light L1 entering the bank 154 by the pores PC of the optical inorganic layer PL may be absorbed by the black bank 154 as illustrated in FIG. 8 (see L1a). The light L1 entering the bank 154 may be scattered by the optical inorganic layer PL and may enter the bank 154 as illustrated in FIG. 8. Among the light L1 entering the bank 154, light that is reflected by the first electrode 151 or the second protective layer 112 and travel back to the outside (see L1b) may be totally reflected by the optical inorganic layer PL with a lower refractive index than the bank 154, may travel into the bank 154, and may be absorbed by the bank 154.

Accordingly, in the display panel according to one embodiment, the optical inorganic layer PL may cover the upper and side surfaces of the bank 154, thereby preventing surface reflection of light (or external light reflection) from the bank 154.

Hereinafter, a display device according to other embodiments will be described. In the following embodiments, the detailed description of the reference numerals or components described in FIGS. 1-9 will be omitted, or the overlapping descriptions thereof will be omitted.

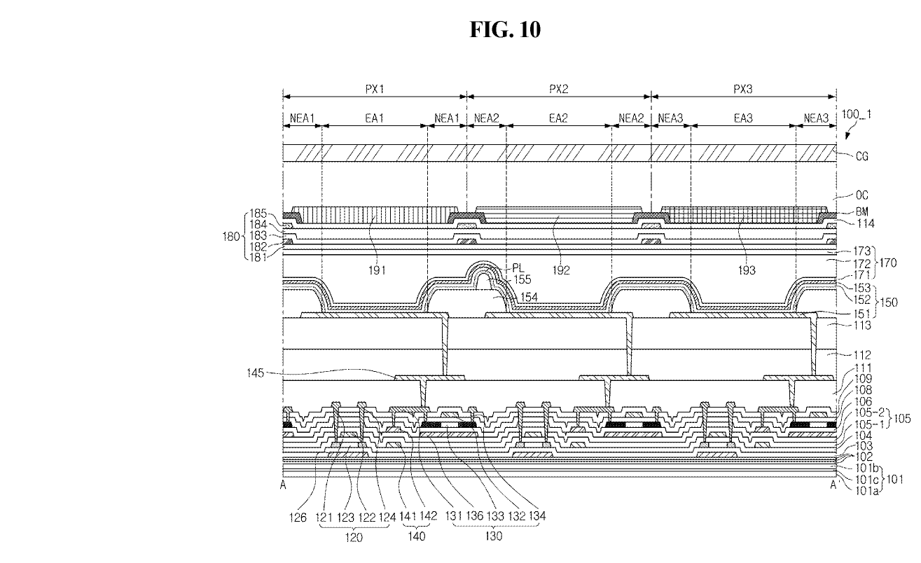

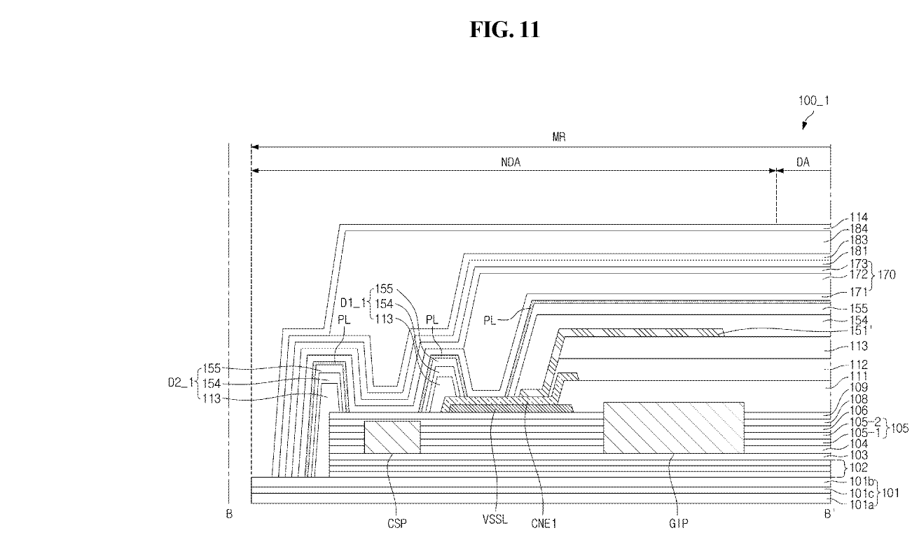

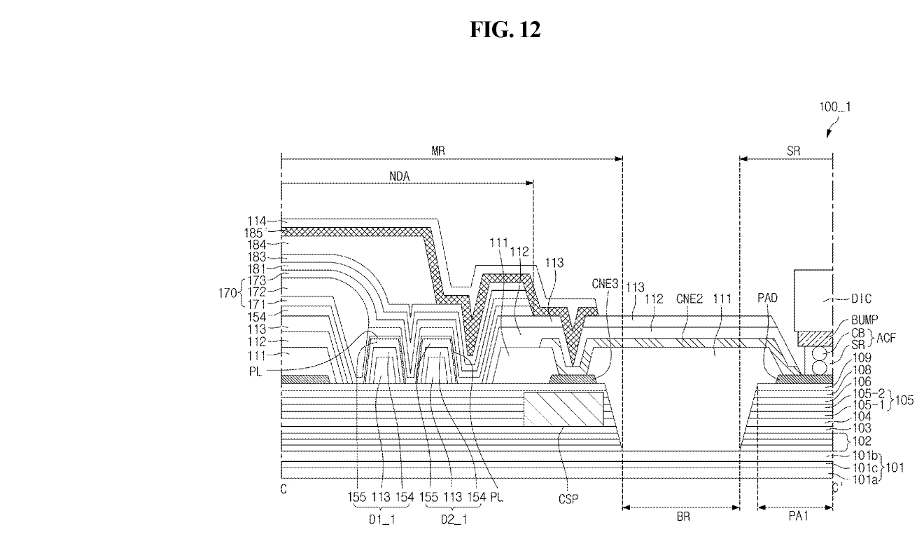

FIG. 10 is a cross-sectional view of a display panel according to still another embodiment. FIG. 11 is a cross-sectional view of a display panel according to still another embodiment. FIG. 12 is a cross-sectional view of the display panel according to yet another embodiment.

Referring to FIGS. 10, 11, and 12, a display panel 100_3 of the display device according to the present embodiment differs from the display panel 100 according to FIGS. 1, 5, and 6 in that it may further include a third protective layer 113 on the second protective layer 112.

More specifically, a display panel 100_3 according to the present embodiment may further include the third protective layer 113 between the second protective layer 112 and the first electrode 151. A material of the third protective layer 113 may include at least one of materials exemplified as the material of the second protective layer 112, but the embodiments of the inventive concepts are not limited thereto.

As illustrated in FIGS. 11 and 12, each of a first dam D1_1 and a second dam D2_1 may include the third protective layer 113 as a first layer and may not include the second protective layer 112, but the embodiments of the inventive concepts are not limited thereto.

The optical inorganic layer PL may overlap the third protective layer 113, which is the first layer constituting each of the dams D1_1 and D2_1.

Even in the embodiments of the inventive concepts, the optical inorganic layer PL may be disposed in only the area in which the spacer 155 is disposed, but is not limited thereto, and may be disposed over the entire non-display area NDA.

Since the remaining parts have been described above in FIGS. 3, 5, and 6, the detailed descriptions thereof will be omitted below.

Since the display panel 100_1 has been described above, the detailed descriptions thereof will be omitted below.

According to the embodiments of the invention, the optical inorganic layer may be disposed on the side and upper surfaces of the bank, and a plurality of pores that allows externally incident light to travel (or scatter) toward the bank may be disposed inside the optical inorganic layer. Accordingly, the bank including a black-based material may absorb externally incident light, thereby reducing external reflectivity.

According to the embodiments of the invention, the optical inorganic layer may be disposed on the side and upper surfaces of the bank, and the refractive index of the optical inorganic layer may be lower than the refractive index of the bank. Accordingly, the light traveling to the optical inorganic layer among the light incident on the bank may travel back to the bank (inducing total reflection) at the interface between the optical inorganic layer and the bank. Accordingly, external light reflectivity may be reduced.

According to the embodiments of the invention, the optical inorganic layer may be disposed on the side and upper surfaces of the dam in the non-display area, thereby reducing or delaying moisture penetration in the non-display area.

According to the embodiments of the invention, the surface reflection of external light may be improved to provide low-reflection display device, thereby achieving low power.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display device, comprising:
a substrate comprising a display area including a plurality of sub-pixels, and a non-display area disposed around the display area;
a first electrode disposed in the sub-pixels;
a bank disposed on the first electrode in the display area and positioned at a boundary between adjacent sub-pixels of the plurality of sub-pixels; and
an optical inorganic layer disposed on the bank and covering side surfaces and an upper surface of the bank,
wherein the bank includes a black-based material, and
wherein a refractive index of the optical inorganic layer is lower than a refractive index of the bank.

2. The display device of claim 1, wherein the optical inorganic layer exposes a central portion of the first electrode.

3. The display device of claim 2, further comprising an organic layer disposed on the optical inorganic layer,
wherein the organic layer is in direct contact with the central portion of the first electrode exposed by the optical inorganic layer.

4. The display device of claim 1, wherein the optical inorganic layer comprises a porous inorganic layer, and the optical inorganic layer has a plurality of pores disposed therein.

5. The display device of claim 4, wherein the plurality of pores each have a diameter of 0.3 μm or more.

6. The display device of claim 1, wherein the optical inorganic layer is in direct contact with the side surfaces and the upper surface of the bank.

7. The display device of claim 1, further comprising a spacer disposed on the bank,
wherein the optical inorganic layer is in direct contact with an upper surface of the spacer.

8. The display device of claim 1, further comprising a dam disposed on the substrate in the non-display area,
wherein the optical inorganic layer overlaps the dam.

9. The display device of claim 8, wherein the optical inorganic layer is in direct contact with side surfaces and an upper surface of the dam.

10. The display device of claim 8, wherein the dam includes a first layer, a second layer disposed on the first layer, and a third layer disposed on the second layer, and
wherein the second layer comprises a bank, the third layer comprises a spacer, and the optical inorganic layer is in direct contact with the spacer.

11. The display device of claim 10, further comprising:
a first transistor disposed between the substrate and the first electrode;
a second transistor disposed between the first transistor and the first electrode;
a connection electrode disposed between the second transistor and the first electrode;
a first protective layer disposed between the second transistor and the connection electrode; and
a second protective layer disposed between the connection electrode and the first electrode,
wherein the first layer comprises the second protective layer.

12. The display device of claim 11, wherein a semiconductor layer of the first transistor comprises polysilicon, and a semiconductor layer of the second transistor comprises an oxide.

13. The display device of claim 8, wherein the optical inorganic layer is in direct contact with an upper surface of the substrate exposed by the dam.

14. A display device, comprising:
a substrate comprising a display area including a plurality of sub-pixels, and a non-display area disposed around the display area;
a first electrode disposed in the sub-pixels;
a bank disposed on the first electrode in the display area and positioned at a boundary between adjacent sub-pixels of the plurality of sub-pixels; and
an optical inorganic layer disposed on the bank and covering side surfaces and an upper surface of the bank,
wherein the bank includes a black-based material, and
wherein a plurality of pores are disposed inside the optical inorganic layer.

15. The display device of claim 14, wherein each of the plurality of pores have a diameter of 0.3 μm or more.

16. The display device of claim 14, wherein each sub-pixel of the plurality of sub-pixels comprises light-emitting areas exposed by the bank, and
wherein the optical inorganic layer overlaps a portion of the light-emitting area.

17. The display device of claim 14, wherein the optical inorganic layer is in direct contact with the side surfaces and the upper surface of the bank.

18. The display device of claim 14, further comprising a spacer disposed on the bank,
wherein the optical inorganic layer is in direct contact with an upper surface of the spacer.

19. The display device of claim 14, further comprising a dam disposed on the substrate in the non-display area,
wherein the optical inorganic layer overlaps the dam.

20. The display device of claim 19, wherein the optical inorganic layer is in direct contact with side surfaces and an upper surface of the dam.
